(19) United States
(12) Patent Application Publication
(10) Pub. No.: US 2012/0274341 A1
(43) Pub. Date: Nov. 1, 2012

(54) RESISTANCE MEASUREMENT CIRCUIT AND MEASURING METHOD EMPLOYING THE SAME

(75) Inventor: YING-BIN FU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/334,435

(22) Filed: Dec. 22, 2011

(30) Foreign Application Priority Data
Apr. 28, 2011 (CN) 201110108626.0

(51) Int. Cl. G01R 27/08

(52) U.S. Cl. 324/691

(57) ABSTRACT

A resistance measurement circuit used in a power circuit includes an analog to digital converter (ADC), a signal control module, and a potentiometer. The ADC can receive an output voltage from the power circuit and convert the output voltage from the power circuit to digital signals. The signal control module compares two consecutive digital signals to establish any voltage difference according to the comparison. If the voltage difference is outside a predetermined voltage range, the signal control module adjusts the resistance of the potentiometer and the output voltage from the power circuit until the voltage difference is within the predetermined voltage range.

### BACKGROUND

1. Technical Field

The disclosure generally relates to integrated circuits, and more particularly to a resistance measurement circuit and a measuring method employing the same used for temperature-compensating circuits.

2. Description of the Related Art

Integrated circuits (ICs) such as power circuits are designed with built in temperature-compensating circuits which allow satisfactory operation across a wide temperature range to compensate for the temperature differences of electronic components and also to stabilize the output voltages of the power circuits, for example. However, in use, to ensure the power circuits can work normally within a predetermined temperature range, different temperature-compensating resistors in the temperature-compensating circuit need to be manually assembled or replaced one by one to establish a desired resistor with matching resistance, which may waste testing time and result in high costs and low accuracy.

Therefore, there is room for improvement within the art.

### BRIEF DESCRIPTION OF THE DRAWINGS

Many aspects of a resistance measurement circuit and a measuring method employing the same can be better understood with reference to the following drawings. The components in the drawings are not necessarily drawn to scale, the emphasis instead being placed upon clearly illustrating the principles of the resistance measurement circuit and measuring method employing the same. Moreover, in the drawings, like reference numerals designate corresponding parts throughout the several views. Wherever possible, the same reference numbers are used throughout the drawings to refer to the same or like elements of an embodiment.

FIG. 1 is a schematic circuit view of one embodiment of a resistance measurement circuit of the disclosure.

FIG. 2 is a flowchart of a measuring method, according to an embodiment of the disclosure.

### DETAILED DESCRIPTION

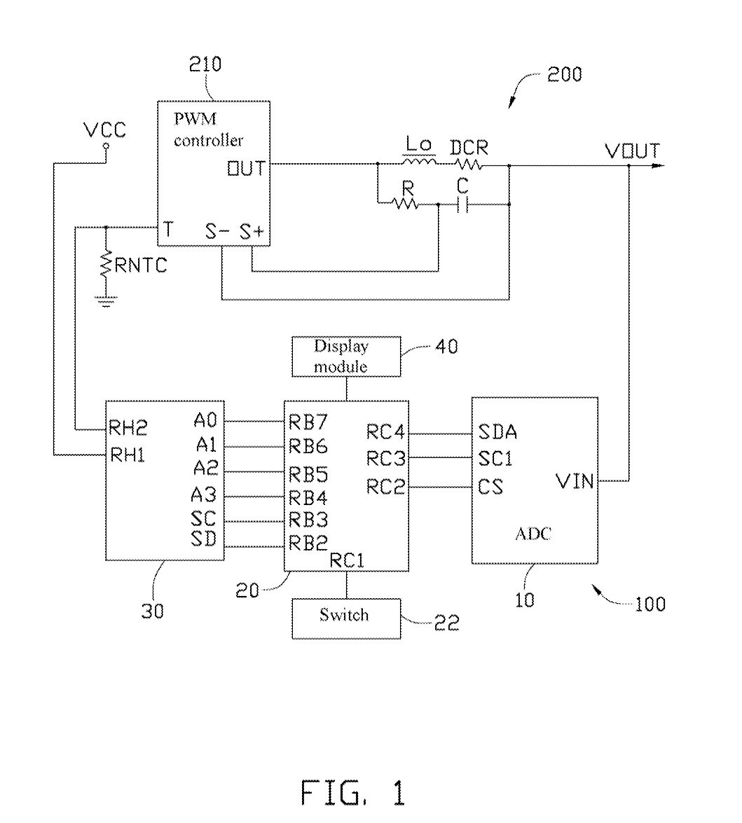

FIG. 1 is a schematic circuit view of one embodiment of a resistance measurement circuit 100 of the disclosure. In this embodiment, the resistance measurement circuit 100 is utilized in a central processing unit (CPU) power circuit 200 and is designed to measure and determine a desired resistance of a temperature-compensating resistor (not shown) which is used to stabilize an output voltage of the CPU power circuit 200.

The CPU power circuit 200 includes a pulse width modulation (PWM) controller 210, a thermistor RNTC, an induction coil Lo, a first resistor R, a second resistor DCR, a capacitor C, and an output terminal VOUT. In this embodiment, the PWM controller 210 includes an output port OUT, a first detection port T, a second detection port S−, and a third detection port S+. The thermistor RNTC, with a resistance varying with temperature, is electrically connected between the first detection port T and ground. The second detection port S− and the third detection port S+ are electrically connected to opposite ends of the capacitor C to measure voltage of the capacitor C.

An inductor is preferred as the induction coil Lo, and the second resistor DCR can be a direct current (DC) resistor. The output port OUT, the first resistor R, the capacitor C and the output terminal VOUT are electrically connected in series in that order, and the output port OUT, the induction coil Lo, the second resistor DCR and the output terminal VOUT are electrically connected in series in that order. Thus, the PWM controller 210 can adjust the output voltage of the output terminal VOUT according to the measured voltage of the capacitor C, and the output terminal VOUT of the PWM controller 210 thus has the desired output voltage value.

The resistance measurement circuit 100 includes an analog to digital converter (ADC) 10, a signal control module 20, a switch 22, a potentiometer 30, and a display module 40. The ADC 10, the switch 22, the potentiometer 30 and the display module 40 are electrically connected to the signal control module 20. The potentiometer 30 is electrically connected to the thermistor RNTC, the first detection port T and a power supply unit VCC. The ADC 10 is further electrically connected to the output terminal VOUT.

In this embodiment, the ADC 10 can be a 24-bit analog-to-digital microchip and includes an input port VIN, a clock port SCL, a data port SDA, and a control port CS. The input port VIN electrically connects to the output terminal VOUT of the CPU power circuit 200 to get the output voltage from the output terminal VOUT. The clock port CSL, the data port SDA and the control port CS electrically connect to the signal control module 20. The ADC 10 converts an output analog voltage from the output terminal VOUT into a digital signal proportional to the magnitude of the voltage, and the digital signal is transmitted to the signal control module 20 via the data port SDA.

The signal control module 20 can be a microcontroller and includes an enable pin RC1, a control pin RC2, a clock pin RC3, a data pin RC4, and a group of input/output (I/O) pins RB2, RB3, RB4, RB5, RB6 and RB7. In this embodiment, the enable pin RC1 is electrically connected to the switch 22, so that when the switch 22 is switched on, the enable pin RC1 activates the signal control module 20. The control pin RC2 is electrically connected to the control port CS of the ADC 10 to control and enable the ADC 10 to record the output voltage of the output terminal VOUT at certain intervals (e.g., 5 seconds or 10 seconds). The clock pin RC3 is electrically connected to the clock pin SCL of the ADC 10. The data pin RC4 is electrically connected to the data port SDA of the ADC 10. The I/O pins RB2-RB7 are electrically connected to the potentiometer 30.

The signal control module 20 compares two consecutive digital signals transmitted from the ADC 10 corresponding to the output voltages of the output terminal VOUT to obtain a voltage difference according to the comparison, and further determines whether or not the voltage difference is within a predetermined voltage range (e.g., between 0.8 mV and 1.2 mV). If the voltage difference is outside the predetermined voltage range, the signal control module 20 transmits a command signal to the potentiometer 30 to adjust the resistance of the potentiometer 30, to further control and adjust the output voltage of the output terminal VOUT. If the current voltage difference is within the predetermined voltage range, the signal control module 20 records and stores the current resistance of the potentiometer 30. If the voltage difference is still within the predetermined voltage range within a certain period of observational time (e.g., 10 or 15 minutes), the signal control module 20 records and stores the current resistance of the potentiometer 30 which is determined as the desired resistance of a temperature compensation resistor in the CPU power circuit 200. Then, a temperature compensation resistor having the desired resistance determined by the resistance measurement circuit 100 may be substituted for the potentiometer 30 and be electrically connected between a power supply unit VCC and a node between the thermistor RNTC and the first detection port T of the PWM controller 210.

In this embodiment, the potentiometer 30 is preferred to a digital potentiometer that carries out the functions of a variable resistor or rheostat and has a adjustable resistance. The potentiometer 30 includes a group of address pins A0, A1, A2 and A3, two data pins SD and SC, and two measurement ports RH1 and RH2. The address pins A0-A3 electrically and respectively connect the I/O pins RB7-RB4 in that order, so that the signal control module 20 can communicate with the potentiometer 30 via the address pins A0-A3, and initialize the potentiometer 30. The data pins SD and SC are electrically connected to the I/O pins RB2 and RB3, respectively, to receive the command signal from the signal control module 20 and send an instantaneous feedback signal to the signal control module 20.

The measurement port RH1 is electrically connected to the power supply unit VCC to power the potentiometer 30, the measurement port RH2 is electrically connected to the node between the thermistor RNTC and the first detection port T of the PWM controller 210. In this embodiment, when the voltage of the thermistor RNTC detected by the first detection port T is equal to a preset voltage of the PWM controller 210, the PWM controller 210 is activated, and changes the output voltage of the output terminal VOUT to achieve a desired output voltage.

The display module 40 can be a touch screen and is electrically connected to the signal control module 20. The display module 40 displays the resistance values of the potentiometer 30 as the values are applied.

Moreover, a loudspeaker can be substituted for the display module 40. The loudspeaker can produce sound to indicate the resistance(s) of the potentiometer 30 as the values change.

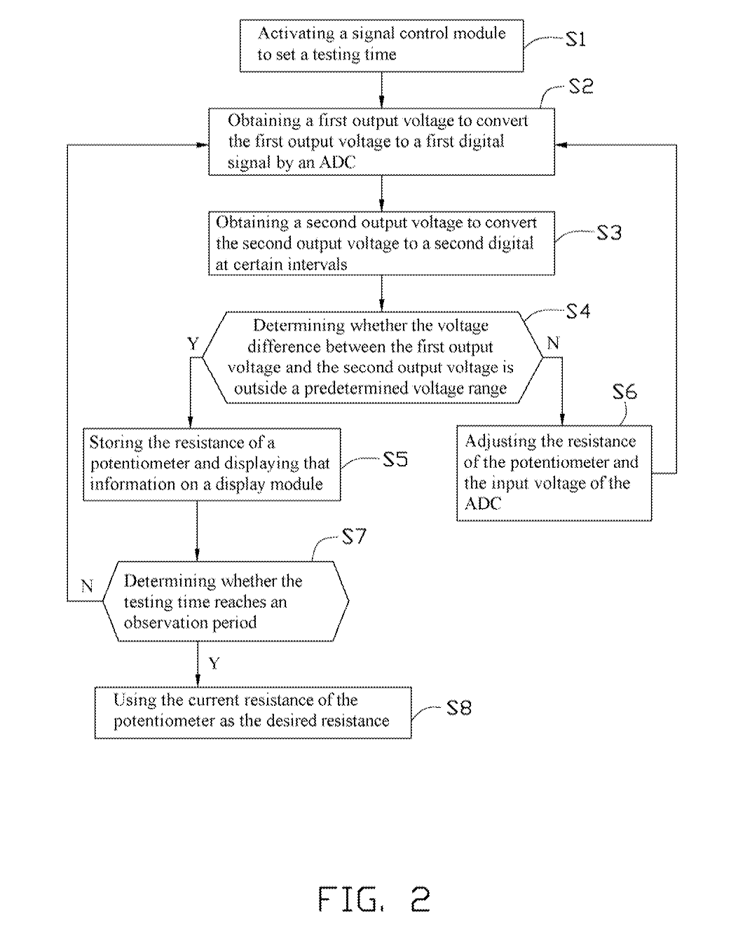

Further referring to FIG. 2, a measuring method for measuring the resistance of a desired temperature-compensating resistor of the CPU power circuit 200 is depicted. The measuring method can use the aforementioned resistance measurement circuit 100, and may include at least the following steps.

In step S1, the switch 22 is switched on, the signal control module 20 is activated, and starts to measure the desired resistance of the temperature-compensating resistor during a testing time (e.g., 10 minutes or 15 minutes).

In step S2, the ADC 10 receives an output voltage V1 from the output terminal VOUT of the CPU power circuit 200, and converts the output voltage V1 to a first digital signal which is transmitted to the signal control module 20 via the data port SDA.

In step S3, the signal control module 20 controls and enables the ADC 10 to receive and record another output voltage V2 from the output terminal VOUT at certain intervals (e.g., 5 seconds or 10 seconds), and the ADC 10 converts the output voltage V2 to a second digital signal which is transmitted to the signal control module 20 via the data port SDA.

In step S4, the signal control module 20 compares the first digital signal with the second digital signal respectively corresponding to the output voltage V1 and the output voltage V2 to establish any voltage difference (which might be 0.8 mV or 1.2 mV for example), according to the comparison to determine whether or not the voltage difference is within the predetermined voltage range. If the voltage difference is within the predetermined voltage range, then the method proceeds to step S5; otherwise, the method proceeds to step S6.

In step S5, the signal control module 20 stores the current resistance of the potentiometer 30 and displays that information on the display module 40 in real-time, then the method proceeds to step S7.

In step S6, the signal control module 20 transmits a signal to adjust the resistance of the potentiometer 30, to control and adjust the output voltage of the output terminal VOUT, and then step S2 is repeated.

In step S7, the signal control module 20 determines whether or not the testing time has finished (e.g., after 15 minutes). If the observation period within the testing time has been reached, then the method proceeds to step S8; otherwise, the step S2 is repeated.

In step S8, the signal control module 20 records and stores the current resistance of the potentiometer 30, having determined that resistance value as the desired resistance of a temperature-compensating resistor in the CPU power circuit 200, and the value of the current resistance of the potentiometer 30 is displayed on the display module 40 in real-time.

In summary, in the resistance measurement circuit 100 of this disclosure, the ADC 10 can obtain a number of output voltages from the output terminal VOUT, and the signal control 20 automatically compares two consecutive output voltages. The signal control module 20 then adjusts the potentiometer 30 appropriately, to further control and change the output voltage of the output terminal VOUT, which can improve the accuracy of the output voltage. Moreover, the measured resistance of the potentiometer 30 can be used as the desired resistance of a temperature-compensating resistor in the CPU power circuit 200 or other power circuits, so the need to frequently and manually assemble and substitute different temperature-compensating resistors for testing in the power circuits is entirely avoided.

In the present specification and claims, the word “a” or “an” preceding an element does not exclude the presence of a plurality of such elements. Further, the word “comprising” does not exclude the presence of other elements or steps other than those listed.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in the matters of shape, size, and arrangement of parts within the principles of exemplary disclosure to the full extent indicated by the broad general meaning of the terms in which the appended claims are expressed.

What is claimed is:

1. A resistance measurement circuit used in a power circuit, comprising:
an analog to digital converter (ADC) electrically connected to the power circuit to receive output voltage from the power circuit;
a signal control module electrically connected to the ADC; and
a potentiometer electrically connected to the signal control module, wherein the ADC converts the output voltage from the power circuit to corresponding digital signals, the signal control module compares two consecutive digital signals to establish a voltage difference according to the comparison, if the voltage difference is outside a predetermined voltage range, the signal control module controls the potentiometer to adjust the resistance and the output voltage from the power circuit until the voltage difference is within the predetermined voltage range.

2. The resistance measurement circuit as claimed in claim 1, further comprising a display module electrically connected to the signal control module, wherein the display module displays the resistance values of the potentiometer.

3. The resistance measurement circuit as claimed in claim 1, wherein the ADC is a 24-bit analog-to-digital microchip and comprises an input port, a clock port, a data port, and a control port, the input port electrically connects the power circuit to achieve the output voltage, the clock port, the data port and the control port electrically connect to the signal control module, the ADC converts the output analog voltage from the power circuit to the digital signal proportional to the magnitude of the voltage, and the digital signal is transmitted to the signal control module via one of the data port.

4. The resistance measurement circuit as claimed in claim 3, wherein the signal control module is a microcontroller and comprises an enable pin, a control pin, a clock pin, a data pin, and a group of input/output (I/O) pins, the control pin is electrically connected to the control port of the ADC to control the ADC to record the output voltage of the power circuit, the clock pin is electrically connected to the clock pin of the ADC, the data pin is electrically connected to the data port of the ADC, and the I/O pins are electrically connected to the potentiometer.

5. The resistance measurement circuit as claimed in claim 3, wherein the signal control module determines whether the voltage difference is outside the predetermined voltage range, if the current voltage difference is within the predetermined voltage range, the signal control module stores the current resistance of the potentiometer, and if the voltage difference is within the predetermined voltage range with a certain period of observational time, the signal control module records and stores the current resistance of the potentiometer which is used as the desired resistance of a temperature compensation resistor in the power circuit.

6. The resistance measurement circuit as claimed in claim 4, wherein the potentiometer is a digital potentiometer and comprises a group of address pins, two data pins, and two measurement ports, the address pins electrically and respectively connect four of the I/O pins, so the signal control module communicates with and initializes the potentiometer via the address pins, the data pins are electrically connected to the other two I/O pins to communicate with the signal control module.

7. The resistance measurement circuit as claimed in claim 6, wherein the power circuit comprises a pulse width modulation (PWM) controller, a thermistor and an output terminal, the thermistor is electrically connected between the PWM controller and ground, the output terminal electrically connects the input port of the ADC to provide the output voltage, the PWM controller controls and adjusts the output voltage of the output terminal, and one of the measurement port is electrically connected to a power supply unit to power the potentiometer, the other measurement port electrically connects the thermistor and the PWM controller.

8. The resistance measurement circuit as claimed in claim 4, further comprising a switch electrically connected to the enable pin of the signal control, wherein the when the switch is switched on, the enable pin is enabled to activate the signal control module.

9. A resistance measurement circuit used in a power circuit to figure out a desired resistance, the power circuit comprising an output terminal, the resistance measurement circuit comprising:
an analog to digital converter (ADC) electrically connected to the output terminal of the power circuit;
a signal control module electrically connected to the ADC to control the ADC to receive different output voltage from the output terminal of the power circuit; and
a potentiometer electrically connected to the signal control module, wherein the ADC converts the output voltage from the output terminal of the power circuit to corresponding digital signals, the signal control module compares two consecutive digital signals corresponding to the two consecutive output voltage, and establishes a voltage difference according to the comparison, if the voltage difference is outside a predetermined voltage range, the signal control module sends a command signal to control the potentiometer to adjust the resistance and the output voltage from the output terminal until the voltage difference is within predetermined voltage range or the comparison has finished, if the voltage difference is within the predetermined voltage range, the signal control module stores the current resistance of the potentiometer as the desired resistance.

10. The resistance measurement circuit as claimed in claim 9, further comprising a display module electrically connected to the signal control module, wherein the display module displays the resistance values of the potentiometer.

11. The resistance measurement circuit as claimed in claim 9, wherein the ADC is a 24-bit analog-to-digital microchip and comprises an input port, a clock port, a data port, and a control port, the input port electrically connects the power circuit to achieve the output voltage, the clock port, the data port and the control port electrically connect to the signal control module, the ADC converts the output analog voltage from the output terminal to the digital signal proportional to the magnitude of the voltage, and the digital signal is transmitted to the signal control module via one of the data port.

12. The resistance measurement circuit as claimed in claim 11, wherein the signal control module is a microcontroller and comprises an enable pin, a control pin, a clock pin, a data pin, and a group of input/output (I/O) pins, the control pin is electrically connected to the control port of the ADC to control the ADC to record the output voltage from the output terminal, the clock pin is electrically connected to the clock pin of the ADC, the data pin is electrically connected to the data port of the ADC, and the I/O pins are electrically connected to the potentiometer.

13. The resistance measurement circuit as claimed in claim 11, wherein the signal control module determines whether the voltage difference is outside the predetermined voltage range, if the current voltage difference is within the predetermined voltage range, the signal control module stores the current resistance of the potentiometer, and if the voltage difference is within the predetermined voltage range within a certain period of observational time, the signal control module records and stores the current resistance of the potentiometer which is used as the desired resistance of a temperature compensation resistor in the power circuit.

14. The resistance measurement circuit as claimed in claim 12, wherein the potentiometer is a digital potentiometer and comprises a group of address pins, two data pins, and two measurement ports, the address pins electrically and respectively connect four of the I/O pins, so the signal control module communicates with and initializes the potentiometer through the address pins, the data pins are electrically connected to the other two I/O pins to communicate with the signal control module.

15. The resistance measurement circuit as claimed in claim 14, wherein the power circuit comprises a pulse width modulation (PWM) controller, a thermistor and an output terminal, the thermistor is electrically connected between the PWM controller and ground, the output terminal electrically connects the input port of the ADC to provide the output voltage, the PWM controller controls and adjusts the output voltage of the output terminal according to the comparison, and one of the measurement ports is electrically connected to a power supply unit to power the potentiometer, the other measurement port electrically connects the thermistor and the PWM controller.

16. The resistance measurement circuit as claimed in claim 12, further comprising a switch electrically connected to the enable pin of the signal control, wherein the when the switch is switched on, the enable pin is enabled to activate the signal control module.

17. A measuring method for measuring the resistance of a temperature-compensating resistor in a power circuit, the measuring method comprising steps of:
obtaining a first output voltage from the power circuit;
obtaining a second output voltage from the power circuit at certain intervals;
comparing the first output voltage with the second output voltage to establish a voltage difference to determine whether the voltage difference is within a predetermined voltage range within a certain period of observational time; and
recording the current resistance of a potentiometer to use the current resistance as the desired resistance of the temperature-compensating resistor.

18. The measuring method as claimed in claim 17, further comprising activating a signal control module to set a testing time.

19. The measuring method as claimed in claim 17, further comprising storing the current resistance of the potentiometer if the voltage difference is within the predetermined voltage range.

20. The measuring method as claimed in claim 17, further comprising transmitting a command signal to control the potentiometer to control and adjust the resistance and the output voltage of the power circuit if the voltage difference is outside the predetermined voltage range.
